(19) United States
(12) Patent Application Publication
(10) Pub. No.: US 2026/0239564 A1
(43) Pub. Date: Aug. 13, 2026

(54) CONVECTIVE COOLING APPARATUS AND METHOD

(71) Applicant: Peter C. SALMON, Mountain View, CA (US)

(72) Inventor: Peter C. SALMON, Mountain View, CA (US)

(21) Appl. No.: 19/225,837

(22) Filed: Jun. 2, 2025

Related U.S. Application Data
(60) Provisional application No. 63/756,741, filed on Feb. 10, 2025.

(51) Int. Cl. H05K 7/20; H05K 1/02; H05K 7/14

(52) U.S. Cl. CPC H05K 7/20263; H05K 1/0203; H05K 7/1492; H05K 7/20236; H05K 7/20254; H05K 7/20772

(57) ABSTRACT

A convective cooling apparatus includes a first metal plate and a second metal plate defining a primary passage therebetween. A metallic insert is disposed within the primary passage. The metallic insert is configured to permit a liquid coolant to flow through the metallic insert from an inlet to an outlet of the primary passage.

### CROSS-REFERENCE TO RELATED APPLICATIONS

This application claims priority to and benefit of U.S. Provisional Application No. 63/756,741, filed Feb. 10, 2025, entitled “CONVECTIVE COOLING APPARATUS AND METHOD,” which is hereby incorporated herein by reference in its entirety.

### TECHNICAL FIELD

This invention relates to the field of fluid-cooled electronic systems, and to convective liquid cooling. More specifically, the present invention relates to an apparatus and method for convective cooling that includes a metallic insert configured to permit a liquid coolant to flow through the metallic insert.

### BACKGROUND

The total thermal resistance (R) of a thermal path is the sum of individual thermal resistances in series. For a path comprising a silicon chip (Si), a thermal interface material (TIM), a copper plate (Cu), and a liquid interface, the thermal resistance is:

$$R = {R}_{Si} + {R}_{TIM} + {R}_{Cu} + {R}_{Conv} \qquad ( 1 )$$

where the conductive resistances R_{Si}, R_{TIM}, and R_{Cu} are given by:

$${R}_{Si} = \frac{{t}_{Si}}{{k}_{Si} {A}_{Si}} \qquad ( 2 )$$

$${R}_{TIM} = \frac{{t}_{TIM}}{{k}_{TIM} {A}_{TIM}} \qquad ( 3 )$$

$${R}_{Cu} = \frac{{t}_{Cu}}{{k}_{Cu} {A}_{Cu}} \qquad ( 4 )$$

and where t=thickness, k=thermal conductivity, and A=chip area. In addition, the convective thermal resistance R_{Conv} is:

$${R}_{Conv} = \frac{1}{{hA}_{contact}} \qquad ( 5 )$$

where h is the convective heat transfer coefficient between the copper plate and the liquid coolant, and A_{contact} is the area of contact between the copper plate and the coolant. In well-designed systems employing the best available thermal materials, the largest component of thermal resistance is usually R_{Conv}, and this is why the current disclosure is largely focused on improving this parameter.

### SUMMARY

According to certain aspects of the present disclosure, a convective cooling apparatus includes a first metal plate and a second metal plate defining a primary passage therebetween. A metallic insert is disposed within the primary passage. The metallic insert is configured to permit a liquid coolant to flow through the metallic insert from an inlet to an outlet of the primary passage.

According to certain aspects of the present disclosure, a thermal sheath for a circuit board assembly includes a body constructed of a thermally conductive material and a piece of porous metallic material affixed to each of at least two opposing external sidewalls of the body. The body defines an internal pocket configured to receive the circuit board assembly. The piece of porous metallic material is configured to permit a liquid coolant to flow through the porous metallic material to enhance heat transfer between the body and the liquid coolant.

According to certain aspects of the present disclosure, a computer server includes a tank configured to contain a flowing liquid coolant and a plurality of computer modules juxtaposed within the tank and at least partially immersed in the flowing liquid coolant. Each of the computer modules includes a circuit board assembly including a plurality of electronic components mounted on a substrate and a thermal sheath substantially enclosing the circuit board assembly. The thermal sheath includes a body constructed of a thermally conductive material. The body has a substantially rectangular prism shape and defines an internal pocket dimensioned to receive and support the circuit board assembly. The body further has an opening providing access to the internal pocket. The thermal sheath includes a piece of porous metallic material affixed to each of at least two opposing external sidewalls of the body. The thermal sheath includes a gasket positioned at the opening. The thermal sheath includes a gasket backing plate operatively associated with the gasket and the body to compress the gasket against a sealing surface, thereby forming a seal to prevent intrusion of the flowing liquid coolant from the tank into the internal pocket. The thermally conductive material of the body and the piece of porous metallic material are configured to transfer heat from electronic components mounted on the circuit board assembly to the flowing liquid coolant.

### BRIEF DESCRIPTION OF THE DRAWINGS

The accompanying drawings, which are incorporated into and constitute a part of this specification, illustrate examples of embodiments. Examples of embodiments, together with the description of example embodiments, explain the principles and implementations of the embodiments.

FIG. 1 illustrates a cross-sectional view of an exemplary metallic foil positioned between two metal plates, in accordance with an embodiment of the present disclosure.

FIG. 2 illustrates an expanded cross-sectional view of a section of the folded metal foil depicted in FIG. 1, in accordance with an embodiment of the present disclosure.

FIG. 3 illustrates a further expanded cross-sectional view of a plated joint at a vertex of the folded metal foil in contact with a metal plate, in accordance with an embodiment of the present disclosure.

FIG. 4 illustrates a cross-sectional view of a convective cooling channel, in accordance with an alternative embodiment of the present disclosure.

FIG. 5 illustrates an expanded cross-sectional view of a metal foil vertex in contact with a metal plate, secured in place by a plated coating, in accordance with an alternative embodiment of the present disclosure.

FIG. 6 illustrates an overlay of two adjacent faces of the folded metal foil of FIG. 4, in accordance with an embodiment of the present disclosure.

FIG. 7 illustrates a cross-sectional view of a perforated metal foil used in a convective cooling channel, in accordance with an embodiment of the present disclosure.

FIG. 8 illustrates in an expanded cross-section a plated joint at a contact area between the metal foil of FIG. 7 and a metal plate, in accordance with an embodiment of the present disclosure.

FIG. 9 illustrates a cross-sectional view of a convective cooling channel having a sinusoidal-shaped metal foil positioned between two metal plates, in accordance with an embodiment of the present disclosure.

FIG. 10 illustrates an expanded cross-sectional view of a section of the sinusoidal-shaped metal foil of FIG. 9, in accordance with an embodiment of the present disclosure.

FIG. 11 illustrates a further expanded cross-sectional view of a plated joint between a sinusoidal-shaped metal foil in contact with a metal plate, in accordance with an embodiment of the present disclosure.

FIG. 12 illustrates a perspective view of a thermal sheath, in accordance with an embodiment of the present disclosure.

FIG. 13 illustrates an expanded view of section AA of FIG. 12, showing perforated faces of a metal foil inserted between each pair of fins, in accordance with an embodiment of the present disclosure.

FIG. 14 illustrates a further expanded view of section BB of FIG. 12, in accordance with an embodiment of the present disclosure.

FIG. 15 illustrates in cross-section a cold plate structure, in accordance with an embodiment of the present disclosure.

FIG. 16 illustrates an expanded plan view of a face of the metal foil of FIG. 15 showing an array of perforations, in accordance with an embodiment of the present disclosure.

FIG. 17 illustrates a cross-sectional view of an exemplary thermal sheath having a body with a defined pocket, and affixed sheets of a porous metallic material, in accordance with an embodiment of the present disclosure.

FIG. 18 illustrates in a cross-sectional view an exemplary computer module configured for liquid cooling, the module incorporating a thermal sheath, a circuit board assembly substantially enclosed in the thermal sheath, and a sealing assembly, in accordance with an embodiment of the present disclosure.

FIG. 19 illustrates in a cross-sectional view an exemplary copper foam having a structured metal structure, particularly an open-celled microporous structure, in accordance with an embodiment of the present disclosure.

FIG. 20 illustrates in a cross-sectional view an exemplary computer server incorporating an array of computer modules juxtaposed in a tank of coolant, wherein the coolant flows through sheets of open-celled copper foam incorporated into each computer module, in accordance with an embodiment of the present disclosure.

FIG. 21 corresponds to cross-section YY of FIG. 21, illustrating the flow of a liquid coolant through a sheet of open-celled copper foam incorporated into the computer module of FIG. 21, in accordance with an embodiment of the present disclosure.

FIG. 22 illustrates in a cross-sectional view another exemplary cold plate assembly wherein an open-celled copper foam is disposed between a pair of metal plates, in accordance with an embodiment of the present disclosure.

FIG. 23 is a flow diagram showing the steps of a method for fabricating a convective cooling apparatus, in accordance with an embodiment of the present disclosure.

### DETAILED DESCRIPTION

Embodiments of a convective cooling apparatus and a convective cooling channel having advanced features for maximizing convective heat transfer are disclosed. In addition, various embodiments of the disclosed convective cooling apparatus and convective cooling channel are utilized in cold plates, thermal sheaths, computer modules, and computer servers.

The efficiency of liquid cooling systems for electronics can be improved by reducing convective thermal resistance (R_{Conv}), which is often the largest bottleneck in a thermal path. Convective heat transfer at a metal:liquid interface in a convective cooling channel can be enhanced by providing metallic structures or inserts within the convective cooling channel or on the surfaces of heat-dissipating components. The metallic structures or inserts have multiple embodiments. In some embodiments, the metallic inserts include a metal sheet formed into a non-planar geometry having a plurality of perforated faces. In other embodiments, the metallic inserts include a piece of porous metallic material having a thickness and being composed of a structured metal defining a network of interconnected micropores.

Many strategies can be used alone or in combination for the metallic structures, including for example without limitation: (i) providing metal features of small size, wherein the ratio of surface area to volume is enhanced; (ii) providing 3D features in the metal surfaces to increase surface area and increase mixing of the coolant; and (iii) providing structural features such as slanted faces or offset perforations in a metal sheet or foil disposed within a convective channel such that the structural features improve mixing of the liquid coolant as it flows directly through the structural features. The improved mixing will increase the heat transfer coefficient at the metal:liquid interface. Embodiments of exemplary metallic structures or inserts include, for example without limitation, shaped, formed, or folded perforated metal sheets and foils, and slabs or sheets of porous metallic materials.

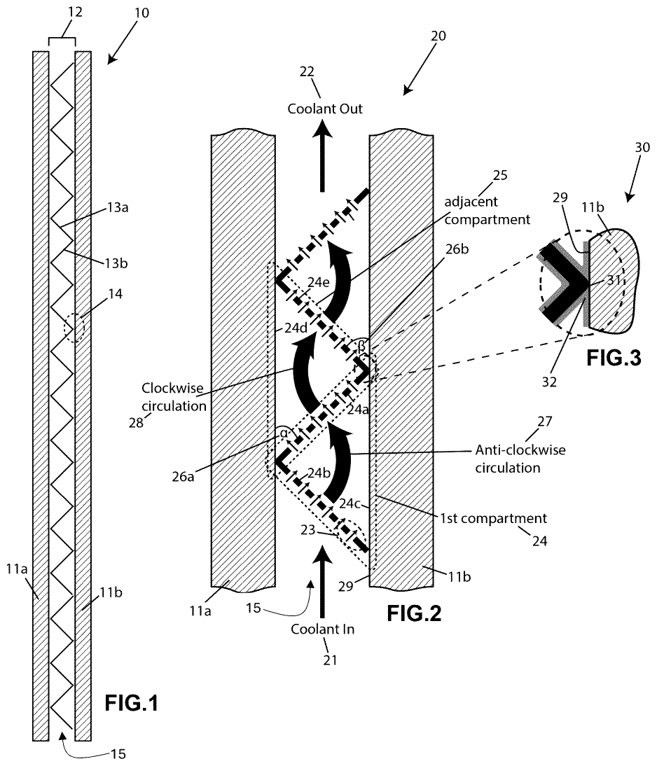

FIG. 1 illustrates in cross-section an exemplary convective cooling channel 10 in accordance with an embodiment of the present disclosure. Cooling channel 10 includes a pair of metal plates 11a, 11b, in a spaced apart face-to-face relationship, thereby defining a primary passage 15 between them, and a metallic insert 12, for example, a shaped metal sheet 12, disposed in the primary passage 15. The shaped metal sheet 12 comprises a folded metal sheet having a plurality of faces 13a, 13b, and vertices 14 where the shaped metal sheet 12 touches the metal plates 11a, 11b.

As shown, the shaped metal sheet 12 has a non-planar structure. In an embodiment, the shaped metal sheet 12 is a thin metal sheet (e.g., without limitation, copper, brass) that is shaped (e.g., folded into accordion-like structures, or formed into a sinusoidal or other wavy shape) and perforated. When placed between the two metal plates 11a, 11b (forming a cooling channel 10, or part of a cold plate, or fins of a heat sink/thermal sheath as are further described herein), the structure formed by the shaped metal sheet 12 provides several advantages.

For example, the shaped metal sheet 12 provides an increase in surface area for heat transfer. The folds, curves, and perforations of the shaped metal sheet 12 significantly increase the contact area between the heated metal of the two metal plates 11a, 11b and a liquid coolant flowing through the cooling channel 10.

The shaped metal sheet 12 also provides an increased structural integrity and ease of assembly. In an embodiment, the shaped metal sheet 12 is designed with spring-like properties for easier assembly and to ensure consistent contact with the two metal plates 11a, 11b that form the walls of the cooling channel 10. In an embodiment, the shaped metal sheet 12 is bonded to the two metal plates 11a, 11b using methods, for example without limitation, like electroless plating (e.g., nickel, for corrosion resistance, mechanical bonding, and thermal coupling), soldering, welding, brazing, or sintering.

FIG. 2 illustrates in expanded cross-section 20 a portion of the convective cooling channel 10 in accordance with an embodiment of the present disclosure. Arrows 21 and 22 show the directions of the coolant input to the primary passage 15 and the coolant output from the primary passage 15. The coolant, for example a liquid coolant, flows through perforations such as 23 in each face of shaped metal sheet 12. In an embodiment, the perforations comprise an array of holes where each hole has substantially the same diameter as shown in FIG. 2. In another embodiment, the holes have varying diameters.

A first compartment 24 is shown having faces 24a, 24b, 24c. An adjacent compartment 25 is shown having faces 24a, 24d, 24e. Face 24a is shown at angle α, 26a, with respect to metal plate 11a which is parallel to the direction of flow of the liquid coolant, and face 24e is shown at angle β, 26b, with respect to metal plate 11b which is also parallel to the direction of flow of the liquid coolant. In an embodiment, angles α and β are about 45 degrees as shown in FIG. 2. In other embodiments, angles α and β have values in a range, for example, between about 30 and about 90 degrees. In an embodiment, angles α and β are the same, but in other embodiments, angles α and β are different.

The shaped metal sheet 12 also promotes mixing of the liquid coolant as it flows through the cooling channel 10. The angled faces of the folds, offset perforations between adjacent layers, and the generally tortuous path created for the liquid coolant induce turbulence and mixing (e.g., alternating circulations). This disrupts the thermal boundary layer and improves the heat transfer coefficient (h). Still referring to FIG. 2, the opposite slants of faces 24b and 24a cause the liquid coolant to have an anti-clockwise circulation 27 in first compartment 24 and a clockwise circulation 28 in adjacent compartment 25. As shown, the liquid coolant flows with alternating circulations in adjacent regions of the cooling channel 10. The alternating circulations effect vigorous mixing of the liquid coolant, thereby increasing convective heat transfer between the liquid coolant and exposed metal components such as faces 24a, 24b, and sidewalls such as 29 of convective cooling channel 10.

FIG. 3 illustrates in expanded cross-section 30 the joining of the shaped metal sheet 12 with metal plate 11b at a contact point 31 formed by vertex 14 of the shaped metal sheet 12 in contact with internal sidewall 29 of metal plate 11b, in accordance with an embodiment of the present disclosure. In an embodiment, a bond is formed using a corrosion resistive coating 32 as shown. For example, coating 32 is electroless plated nickel, providing the desired mechanical bonding as well as strong thermal coupling and corrosion resistance. In other embodiments, the shaped metal sheet 12 is bonded to internal sidewalls 29 of the metal plates 11a, 11b using soldering, welding, brazing, or sintering.

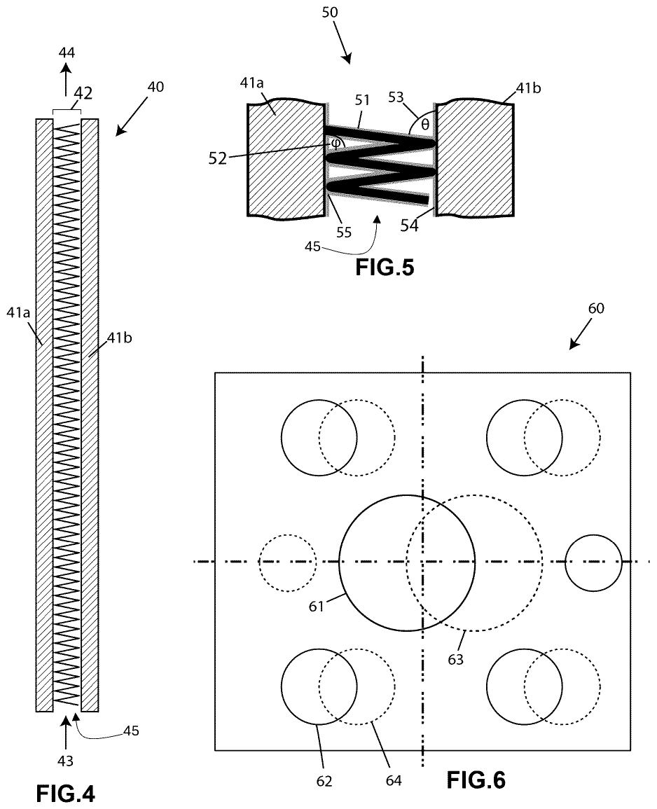

FIG. 4 illustrates in cross-section an exemplary convective cooling channel 40 in accordance with an embodiment of the present disclosure. In this embodiment, cooling channel 40 includes metal plates 41a, 41b, in a spaced apart face-to-face relationship, thereby defining a primary passage 45 between them. In this embodiment, a metallic insert 42, or shaped metal sheet 42 is disposed in the primary passage 45. The shaped metal sheet 42 is also referred to as a shaped metal spring 42. The shaped metal spring 42 comprises a plurality of faces, disposed in a non-planar structure. The directions of liquid coolant flow in 43 to the primary passage 45 and coolant flow out 44 from the primary passage 45 are shown. In an embodiment, one or more surfaces of the metal plates 41a, 41b and the shaped metal spring 42 is textured or roughened to increase convective thermal transfer between them and the liquid coolant.

FIG. 5 illustrates in an expanded cross-section a portion 50 of the convective cooling channel 40, in accordance with an embodiment of the present disclosure. Metal plates 41a, 41b are shown. A face 51 of the shaped metal spring 42 is shown at angle θ, 53, with respect to internal sidewall 54 of metal plate 41b which is parallel to the direction 43 of liquid coolant flow. Increasing values of 0 advantageously result in greater surface areas of the shaped metal spring 42 contained within the convective cooling channel 40 and exposed to the liquid coolant. Since the coefficient of convective heat transfer increases with increased surface area, it may be advantageous to employ values of 0 such as 80° or 85°. In an embodiment some or all of the plurality of faces of the shaped metal spring 42 and the sidewalls 54 are textured or roughened, to increase both adhesion and thermal coupling of the shaped metal spring 42 to the sidewall 54 on subsequent attachment.

As described in reference to FIG. 3, a corrosion-resistant coating 55 serves to mechanically bond and thermally couple vertices of the shaped metal spring 42 to internal sidewalls such as 54 of the metal plates 41a, 41b. In an embodiment the metal plates 41a, 41b, are fabricated using pure copper such as 1100 copper, and the shaped metal spring 42 is fabricated using alloy 260 brass, and the corrosive resistant coating 55 comprises electroless nickel, with the shaped metal spring 42 plated in situ, within the internal sidewalls 54 of the metal plates 41a, 41b, to create mechanical bonds between the shaped metal spring 42 and the sidewalls 54.

The bonds are required to stabilize the shaped metal spring 42 within metal plates 41a, 41b while liquid coolant flows through perforations of the shaped metal spring 42 and asserts pressure on faces such as 51 of the shaped metal spring 42. In other embodiments, the shaped metal spring 42 may be bonded to internal sidewalls 54 of the metal plates 41a, 41b using soldering, welding, brazing, or sintering. A strong mechanical bond also provides strong thermal coupling which is important for overall thermal performance. The use of brass instead of copper for the shaped metal spring 42 is motivated by the greater elasticity of brass compared with copper. Spring-like properties in the shaped metal spring 42 are important during their assembly into the spaces between metal plates 41a, 41b, for creating an even distribution of each shaped metal spring 42 in its associated primary passage 45. An even distribution is achieved when the angles q, 52, and 0, 53 are approximately consistent along the length of the shaped metal spring 42. Additionally, the shaped metal spring 42 may be stretched to reduce its width to facilitate initial insertion into the primary passage 45. However, after insertion the shaped metal spring 42 is required to recover from its stretched condition and settle with points of contact at vertices of the shaped metal spring 42.

In an embodiment the liquid coolant is filtered distilled water that is treated with an anti-microbial agent. The anti-microbial agent provides protection against an accumulation of foreign substances that may include microorganisms, for example, such as bacteria, viruses, fungi, and parasites. In another embodiment nucleate boiling is enabled to increase convective heat transfer. Additional embodiments may employ different coolants such as a dielectric fluid, glycol, or a refrigerant, or any combination thereof. Single or two-phase cooling may be employed.

At the system level an external cooling loop is required to cool and recirculate the coolant for single or two-phase cooling. Two-phase cooling will also require a condenser in the cooling loop. In an embodiment, required cooling loop features are provided by a coolant distribution unit (CDU).

FIG. 6 illustrates an overlay 60 of two adjacent shaped metal spring 42 faces that have been pressed together. Perforations 61, 62, are shown with different hole diameters. FIG. 6 employs circles having solid lines to represent holes in an upper face of the overlay and circles having dotted lines to represent holes in a lower face of the overlay. Examples of offset hole pairs include 61, 63, and 62, 64. In accordance with an embodiment of the present disclosure, liquid coolant flowing through offset holes flows laterally as well as longitudinally in the convective cooling channel 40 and thereby receives more mixing than coolant flowing through non-offset holes. More mixing results in higher convective heat transfer.

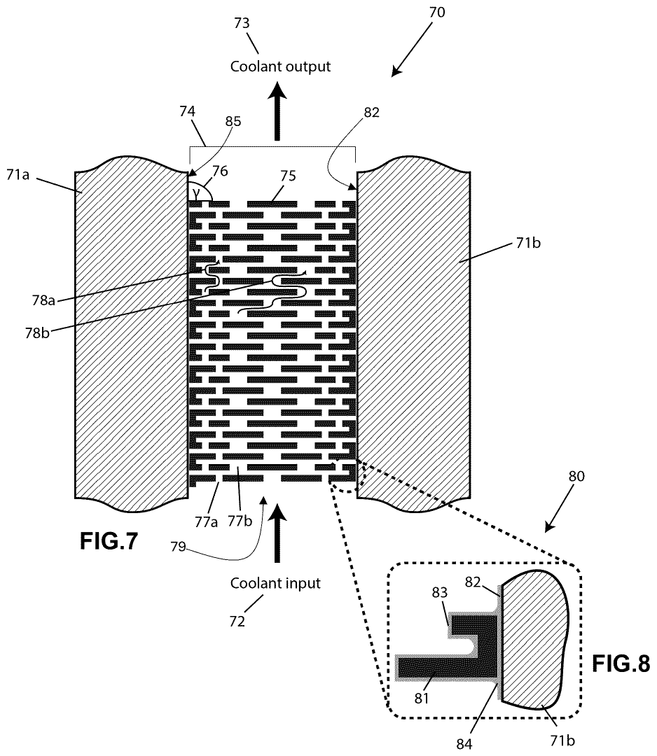

FIG. 7 illustrates a cross-sectional view of another exemplary convective cooling channel 70, in accordance with an embodiment of the present disclosure. Metal plates 71a, 71b are shown in a spaced apart face-to-face relationship, thereby defining a primary passage 79 between them. Coolant input 72 and coolant output 73 are shown as input and output to the primary passage 79. A perforated metallic insert 74 or shaped metal sheet 74 is shown disposed in the primary passage 79. A plurality of faces such as 75 of the shaped metal sheet 74 are disposed at an angle γ, 76, of 90°, forming a non-planar structure. The shaped metal sheet 74 may comprise an elastic material with spring-like properties. The width of the shaped metal sheet 74 having the spring-like properties is preferably oversized relative to the spacing of the metal plates 71a, 71b so that each face of the shaped metal sheet 74 will be curved under compression (not shown) and contact points between the shaped metal sheet 74 and the internal sidewalls 82, 85 of the respective metal plates 71a, 71b will be reliably established, despite manufacturing tolerances affecting the gap between the metal plates 71a, 71b. Offset holes of different diameters 77a, 77b, are shown, contributing to good mixing of the coolant. Coolant flow paths 78a, 78b show the coolant weaving through varying spring apertures, again contributing to good mixing of the coolant.

FIG. 8 illustrates in expanded cross-section 80 bonding of portion 81 of the shaped metal sheet 74 to metal plate 71b at internal sidewall 82, in accordance with an embodiment of the present disclosure. A corrosion-resistant coating 83 is applied as a build-up layer to the convective cooling channel assembly, including the metal plates 71a, 71b and the perforated shaped metal sheet 74 in situ, creating a mechanical bond and good thermal coupling 84 between the portion 81 and the sidewall 82. In other embodiments, the shaped metal sheet 74 is bonded to internal sidewalls 82, 85 of the respective metal plates 71a, 71b using soldering, welding, brazing, or sintering.

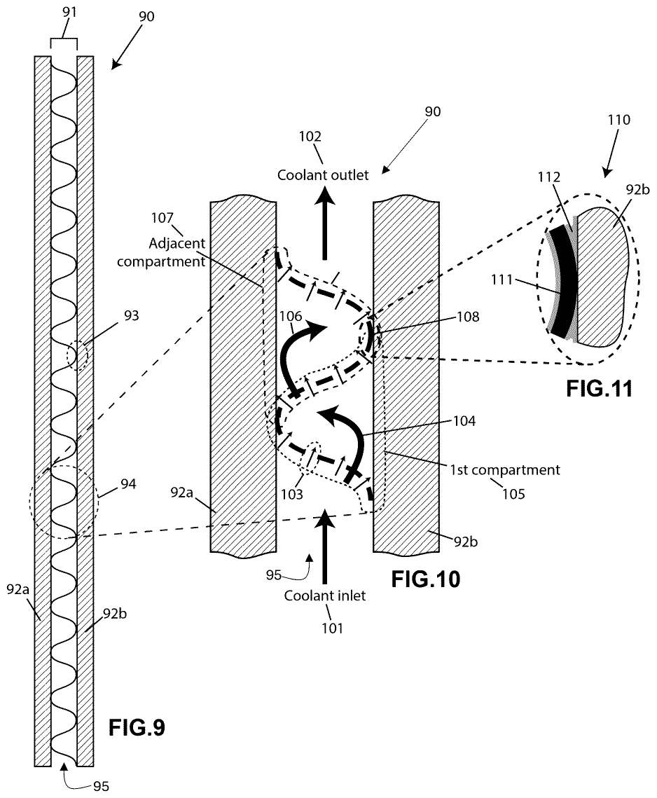

FIG. 9 illustrates a cross-sectional view of another exemplary convective cooling channel 90 comprising a metallic insert 91 or shaped metal sheet 91 having a sinusoidal shape disposed in a primary passage 95 formed between metal plates 92a, 92b, in accordance with an embodiment of the present disclosure. A point of contact 93 between the shaped metal sheet 91 and metal plate 92b is shown. Portion 94 of the shaped metal sheet 91 includes a cycle of the sinusoidal shape. In an embodiment, a rolling process is employed to create the sinusoidal shape. In an embodiment, the perforations in the shaped metal sheet 91, as shown in FIG. 10, are punched as part of the rolling process.

FIG. 10 illustrates in expanded cross-section the convective cooling channel 90. The direction of coolant flow through the primary passage 95 is shown by coolant inlet, 101, and coolant outlet, 102. Coolant flow through an individual perforation is shown, 103. An anticlockwise circulation, 104, is shown in a first compartment, 105, and a clockwise circulation 106 is shown in an adjacent compartment 107. The counter-rotating circulations serve to increase mixing of the coolant, thereby increasing convective heat transfer between the coolant and the exposed metal surfaces within channel 90. A point of contact, 108, is also shown.

FIG. 11 illustrates in further expanded cross-section 110 point of contact 108, in accordance with an embodiment of the present disclosure. A portion, 111, of the shaped metal sheet 91 is shown touching a sidewall of metal plate, 92b, and is mechanically bonded and thermally coupled to the sidewall using corrosion-resistant coating 112. In an embodiment, the corrosion-resistant coating 112 is applied using a build-up process with the shaped metal sheet 91 in situ, disposed within the convective cooling channel 90. In other embodiments, the shaped metal sheet 91 is bonded to internal sidewalls of the metal plates 92a, 92b using soldering, welding, brazing, or sintering.

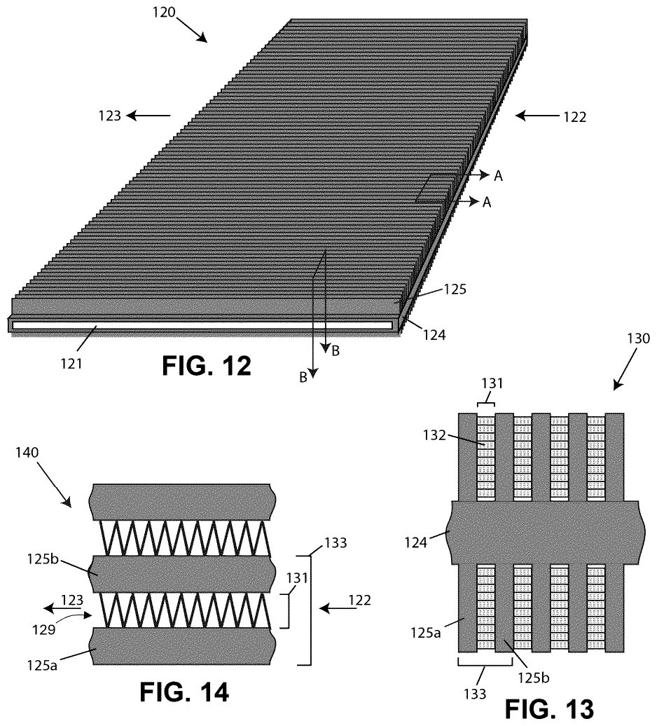

FIG. 12 illustrates an exemplary thermal sheath 120. In an embodiment, the thermal sheath 120 comprises a body 124 constructed of a thermally conductive material, for example without limitation, such as copper. In an embodiment the body 124 has a substantially rectangular prism shape. In other embodiments, the body 124 has other shapes suitable for housing a circuit board assembly. In another embodiment, the circuit board assembly is replaced with an assembly comprising electronic components mounted on a semiconductor wafer. In a further embodiment the circuit board assembly is replaced with a semiconductor wafer, the wafer having circuits fabricated thereon, and the wafer free of mounted electronic components.

Adjacent fins 125 of sheath 120 constitute an exemplary pair of metal plates that are arranged in a convective cooling channel, for example, like the metal plates 92a, 92b of the cooling channel 90 shown in FIG. 9. A metallic insert 131, for example a perforated and shaped metal sheet 131 (see FIG. 13), is disposed in the primary channel formed between each pair of fins 125, to improve convective heat transfer between the coolant and the metal surfaces exposed within the channel, in accordance with an embodiment of the present disclosure.

Still referring to FIG. 12, an opening 121 is shown in the body 124, for inserting an electronic assembly, for example, a circuit board assembly or a semiconductor wafer assembly, to be cooled. The electronic assembly typically includes a substrate having electronic components mounted thereon, wherein the components have a maximum height of around 0.8 mm. Accordingly, stacked high bandwidth memory (HBM) packages can be used, having a height of 775 μm for HBM4 according to a JEDEC standard, compatible with a width of around 2.2-2.6 mm at opening 121. The flow of coolant in, 122, and coolant out, 123, is parallel to the fins, 125. Body 124 substantially encloses the electronic assembly and prevents coolant intrusion from damaging electronic components bonded to a substrate of the electronic assembly. In a system embodiment such as a server (described further below), the opening 121 is sealed with a gasket (not shown) and the substrate of the electronic assembly protrudes through the gasket for connecting signals and power.

A heat sink having cooling fins 125 may comprise convective cooling channels as described herein, where each space between adjacent cooling fins 125 is a convective cooling channel. In different embodiments the spaced apart metal plates in face-to-face relation in any of the above-described embodiments, for example metal plates 11a and 11b, 41a and 41b, 71a and 71b, or 92a and 92b, are planar, or they can encircle the heat dissipating components in a cylindrical form, thereby creating a tubular channel, for example.

FIG. 13 illustrates an expanded cross-sectional view 130 of section A-A of FIG. 12. The shaped metal sheet 131 has planar faces such as 132, or curved features such as provided by a sinusoidal shape, and each face or curved feature includes an array of perforations through which the coolant flows, in accordance with embodiments of the present disclosure. A convective cooling channel 133 comprises the shaped metal sheet 131 and a pair of fins 125a, 125b, and is configured for coolant to flow through the primary passage formed between the pair of fins 125a, 125b.

FIG. 14 illustrates a further expanded cross-sectional view 140 of section B-B of FIG. 12. From a viewpoint above the thermal sheath 120 shown in FIG. 12, FIG. 14 shows the fins 125a, 125b, in a spaced apart face-to-face relationship, forming a primary passage 129 between the fins 125a, 125b. FIG. 14 further shows a shaped metal sheet 131, which comprises folded planar faces in this example, and convective cooling channel 133, in accordance with an embodiment of the present disclosure. The flow directions of coolant in, 122, and coolant out, 123, are shown. In a further embodiment, the shaped metal sheet 131 is replaced with a porous metallic material, for example, a sheet of open-celled metal foam 183, to be further described below.

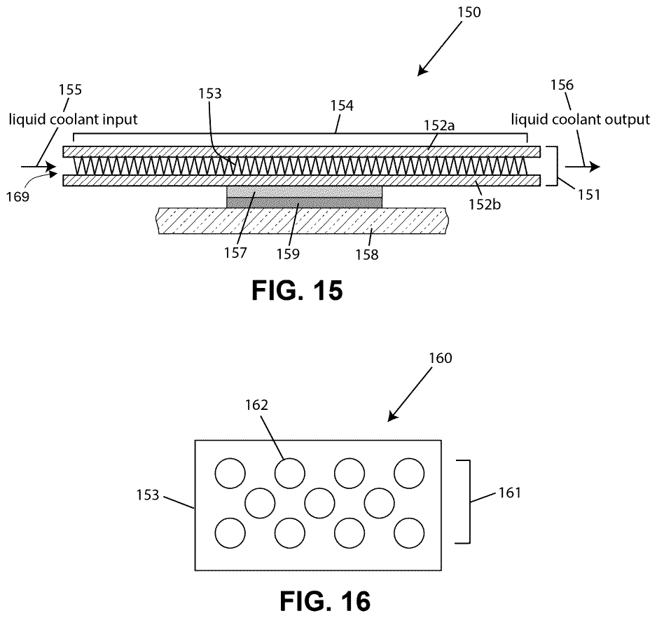

FIG. 15 illustrates in cross-sectional view 150 an exemplary cold plate 151, in accordance with an embodiment of the present disclosure. The exemplary cold plate 151 is a set of plates, typically metal, designed to mount on a heat-generating component (like a CPU or GPU), and incorporating the internal cooling channel with a metallic insert that is a formed metal sheet or a piece of porous metal material in the internal cooling channel. For example, metal plates 152a and 152b are shown in a spaced apart face-to-face relationship, forming a primary passage 169 between them. A formed metal sheet 154 is fabricated by folding a planar sheet of metal, creating faces such as face 153. The formed metal sheet 154 is perforated, as shown in FIG. 16. The formed metal sheet 154 is inserted between the metal plates 152a and 152b and attached at contact points on inwardly facing sidewalls of the metal plates 152a and 152b. The formed metal sheet 154, also described as metal spring 154, may be slightly compressed in the lateral direction so that vertices of the metal spring 154 reliably form contact points with the sidewalls of the metal plates 152a and 152b, enabling the contact points to become points of adhesion with the application of a corrosion-resistant coating, as previously described.

FIG. 15 shows the direction 155 of liquid coolant into the cold plate 151 and the direction 156 of liquid coolant out of the cold plate 151. An electronic component 159 is shown flip chip attached to a substrate 158 and thermally coupled to the cold plate 151 using a thermal interface material (TIM) 157. Chip 159 may be a high-powered chip, such as a B200 chip manufactured by NVIDIA CORPORATION, dissipating heat at a rate of 1200 watts for example, made possible by the cooling provided by the cold plate 151. Multiple chips or other heat-producing electronic components may be thermally coupled to one or both sides of cold plate 151.

FIG. 16 illustrates in an expanded plan view 160, a face 153 of the formed metal sheet 154 of FIG. 15, in accordance with an embodiment of the present disclosure. In an embodiment, face 153 includes an array 161 of perforations 162, enabling liquid coolant to flow through the perforations 162. In an embodiment, array 161 includes perforations 162 having different diameters, and different distributions across the face 153. In another embodiment, the array 161 includes perforations 162 having the same diameter across the face 153. In an embodiment, the perforations 162 are fabricated, for example without limitation, by punching, stamping, or laser drilling, or by other manufacturing methods as may be known in the art.

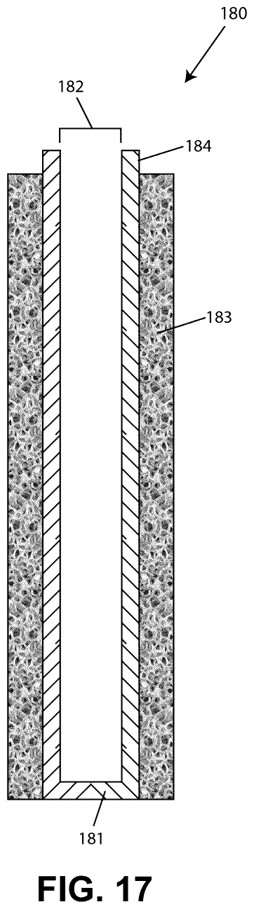

Referring to FIG. 17, an exemplary thermal sheath is illustrated in a cross-sectional view, in accordance with an embodiment of the present disclosure. In an embodiment, the thermal sheath 180 includes a body 181 constructed of a thermally conductive material, for example without limitation, copper. In other embodiments, suitable thermally conductive materials include aluminum and ceramic materials such as aluminum nitride.

In an embodiment, the thermal sheath 180 has a substantially rectangular prism shape. Body 181 includes an internal pocket 182 configured to receive a circuit board assembly, to be further described below. Body 181 comprises a material that is impervious to the chosen liquid coolant. Placement of the circuit board assembly within the internal pocket 182 of the body 181 allows the circuit board assembly to be cooled by the liquid coolant while protecting it from direct contact with the liquid coolant.

In an operating cooling environment, a piece of porous metallic material 183 is affixed to at least one external sidewall 184 of the body 181, to enhance heat transfer between the body 181 and an external liquid coolant flowing around the body 181. In an embodiment, the piece of porous metallic material 183 is affixed to each of at least two opposing external sidewalls 184 of the body 181. In an embodiment, one or more of the external sidewalls 184 of the thermal sheath 180 includes fins (like the fins 125 in FIG. 12 above) between which the formed metal sheet 131 or the piece of porous metallic material 183 is placed.

It is noted that the piece of porous metallic material 183 is another embodiment of a metallic insert that can be substituted for the formed metal sheet 12, 42, 75, 91, 131, and 154 in the respective embodiments of the convective cooling channels 10, 40, 70, 90, 133, as well as the cold plate 151 as described above. In an embodiment, the piece of porous metallic material 183 comprises an open cell copper foam 183 as shown in FIG. 17. For example, the open cell copper foam 183 can be a material having varying pores per inch and a varying relative density. In an embodiment, the piece of porous metallic material 183 is a woven fabric of copper wires. A woven fabric of copper wires includes weave openings that act like openings in a copper foam. Whether an open cell copper foam or a woven fabric of copper wires, the piece of porous metallic material 183 can be shaped in various forms such as a sinusoidal form or a folded sheet form, as previously described for the formed metal sheet 12, 42, 75, 91, 131, and 154. As previously

When used within a cooling channel 10, 40, 70, 90, 133 or a cold plate 151, the piece of porous metallic material 183 has a thickness such that it substantially occupies the primary passage by spanning the space between the corresponding two metal plates, for example, the primary passage 45 between the two metal plates 41a, 41b. The interconnected microporous structure of the piece of porous metallic material 183 allows coolant to flow directly through it, offering a very high surface area-to-volume ratio and inherent mixing. Affixation of the piece of porous metallic material 183 to an external surface, for example, to the external sidewalls 184 of the thermal sheath 180, offers the advantages of a very high surface area-to-volume ratio and inherent mixing to enhance heat transfer from the external sidewalls of the thermal sheath 180 to an external liquid coolant.

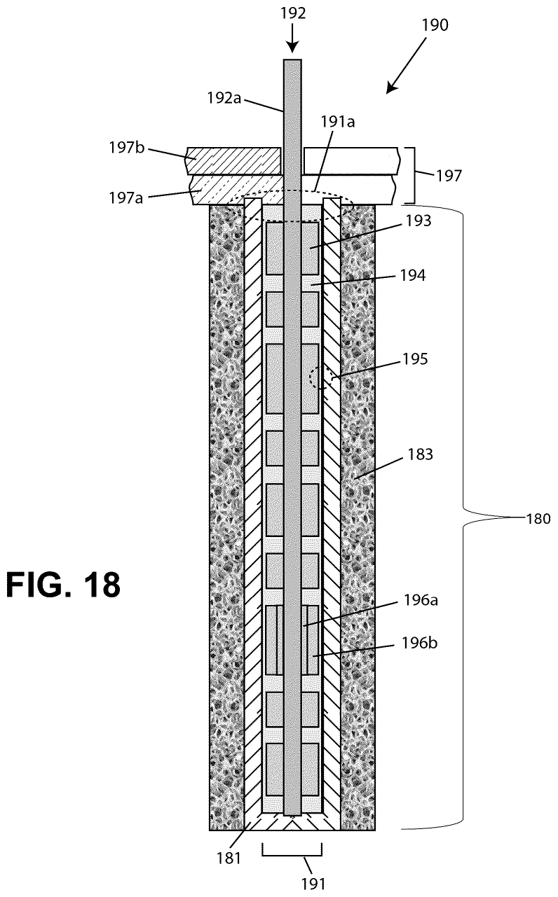

Referring to FIG. 18, an exemplary computer module 190, is shown in accordance with an embodiment of the present disclosure. The computer module 190 is designed to be immersed in a tank of liquid coolant. In an embodiment, the computer module 190 includes a thermal sheath 180 having a body 181 that substantially encloses a circuit board assembly 191. The circuit board assembly 191 comprises a substrate 192 and mounted electronic components 193 such as computer chip 193. Enclosing the circuit board assembly 191 within the body 181 protects the electronic components 193 mounted on the substrate 192 from intrusion of an external liquid coolant. As previously described, in other embodiments the circuit board assembly may be replaced with a semiconductor wafer having circuits fabricated thereon, with or without electronic components mounted on the semiconductor wafer.

In an embodiment, an access opening 191a is provided in the body 181 so that signals and power can be connected to circuit board assembly 191. A sealing assembly 197 includes a gasket 197a and a backing plate 197b, configured to create a water-tight seal at the opening 191a. Gasket 197a is compressed against end faces of body 181, thereby forming a seal to prevent intrusion of flowing external liquid coolant from the tank into circuit board assembly 191.

In an embodiment, the electronic components mounted on substate 192 have a preferred maximum height of about 0.8 mm, sufficient to accommodate stacked memory devices such as HBM4 with a JEDEC specified package height of 775 micrometers. In an embodiment, the substrate 192 includes an extended portion 192a that is free of mounted electronic components 193 and includes conductive traces for connecting to a socket, to be further described.

In an embodiment, a thermal interface material (TIM) 194 is disposed around the electronic components 193, and a small gap 195 filled with TIM 194 exists between the back face of an electronic component 193, such as semiconductor chip 193, and an internal sidewall of the body 181. In an embodiment, the gap 195 measures, for example, a few micrometers.

Semiconductor chips 193 that provide backside power distribution are typically thinner than chips that don't provide this feature because of a manufacturing need to expose through-silicon vias (TSVs) in the chip. Accordingly, thin chip 196a is provided with a spacer chip 196b having high thermal conductivity. In an embodiment, the spacer chip 196b comprises silicon or aluminum nitride as examples, and may be coupled to thin chip 196a using a thermal interface material.

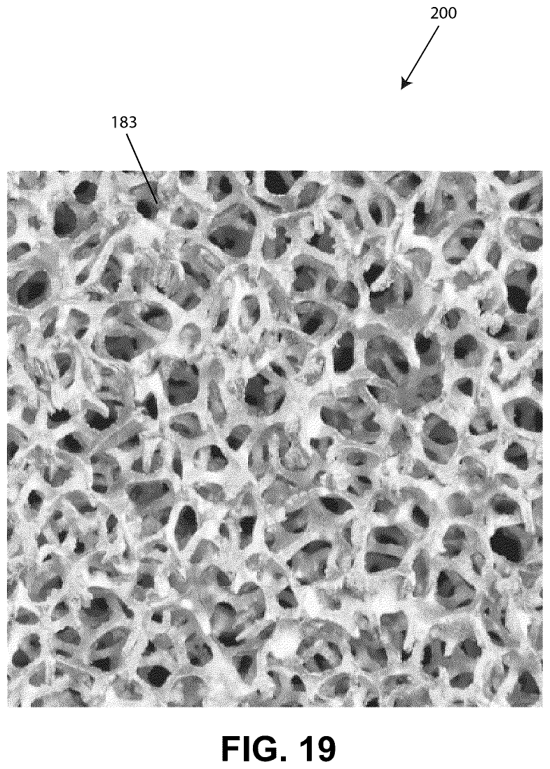

FIG. 19 illustrates in a plan view a porous metallic material 183 having a microporous structure configured to permit the passage of a liquid coolant through the structure, in accordance with embodiments of the present disclosure. The porous metallic material 183 shown is an open-celled copper foam. It can be produced with varying parameters such as pores per inch (PPI) in a range from 5 to 80 PPI, and relative density in a range from 3% to 15%. It can also be produced in pieces of varying thickness. The porous metallic material 183 is used to enhance heat transfer at an interface, for example as described above, between the body 181 of a thermal sheath 180 and an external liquid coolant, or between a pair of metal plates (e.g., 41a, 41b) and a liquid coolant flowing between the metal plates. Heat transfer is increased with micro-sized pores having a high surface-area-to-volume ratio and is also increased due to the mixing effect of the porous structure.

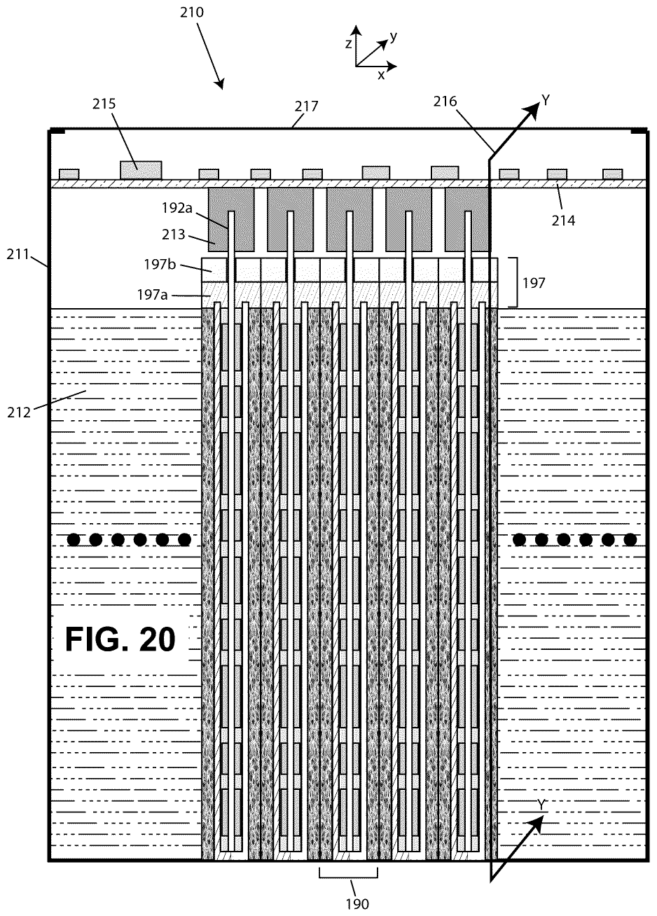

FIG. 20 illustrates in a cross-sectional view a computer server 210, in accordance with embodiments of the present disclosure. Server 210 includes a tank 211 configured with a plurality of computer modules 190 juxtaposed and at least partially immersed in a liquid coolant 212 that flows through the tank 211 in an operating server. Heat generated at junctions of electronic components 193 disposed within each computer module 190 follows a path comprising a TIM 194 and a sidewall 184 of sheath body 181 before reaching liquid coolant flowing through a porous metallic material 183. The materials of the TIM 194 and the sheath body 181 are chosen with the highest possible thermal conductivity, to minimize the ΔT created between the junction temperature of a mounted electronic component 193 and the liquid coolant. Additionally, the porous metallic material 183 is configured to maximize heat transfer between the sheath body 181 and the liquid coolant 212.

A sealing assembly 197 is shown, including a gasket 197a and a backing plate 197b as previously described. Each computer module 190 is coupled to a motherboard 214 via a socket 213. As previously described, extended portion 192a of substrate 192 is free of mounted electronic components 193 and includes conductive traces (not shown) for connecting to socket 213. The motherboard 214 includes terminals configured to connect to corresponding terminals of socket 213, thereby facilitating communication between the electronic components 193 of the computer module 190 and the motherboard 214. The motherboard 214 includes components such as chip 215 that may implement an electronic function, an RF function, an optical function, or an electro-optical function. Lid 217 of tank 211 may comprise a non-metallic material to support RF communications from motherboard 214 to devices or systems external to server 210.

Coolant 212 may be selected from the group consisting of treated water, a dielectric fluid, a refrigerant, glycol, or any combination thereof. In an embodiment, the treated water includes an anti-microbial agent that provides protection against an accumulation of foreign substances that may include microorganisms, such as bacteria, viruses, fungi, and parasites.

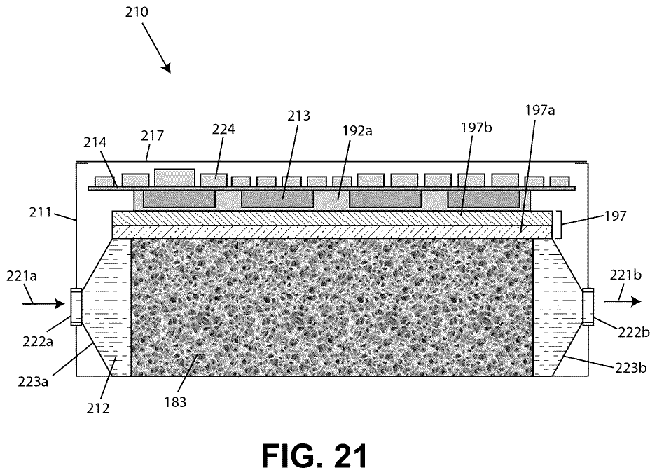

FIG. 21 illustrates a cross-sectional view of the server 210 taken generally along the lines Y-Y of FIG. 20 looking transverse to the view in FIG. 20, in accordance with an embodiment of the present disclosure. Tank 211 is shown partially filled with liquid coolant 212. Sealing assembly 197 is shown, including gasket 197a and backing plate 197b. Socket 213 is shown connecting to extended portion 192a of substrate 192, and to motherboard 214. Liquid coolant 212 enters tank 211 at tank input 221a using a fluid coupling 222a and exits at tank output 221b using a coupling 222b. A coolant distribution plate 223a is shown at the tank input, and coolant distribution plate 223b is shown at the tank output. A sheet of porous metallic material 183 is shown, wherein the microporous property of sheet 183 enables liquid coolant 212 to flow through the illustrated module 190 of server 210.

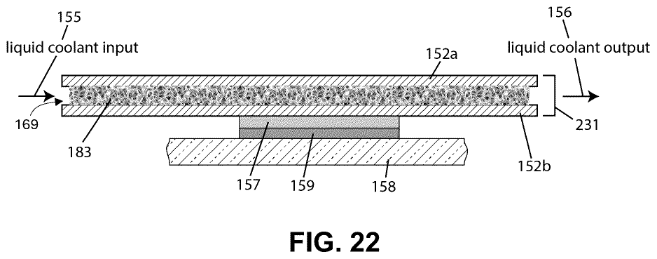

FIG. 22 illustrates a cross-sectional view of another exemplary embodiment of a cold plate 231, in accordance with an embodiment of the present disclosure. Similar to the embodiment shown in FIG. 15, metal plates 152a and 152b are shown in a spaced-apart face-to-face relationship, creating a primary channel 169 between them. A sheet of porous metallic material 183 is disposed in the primary channel 169, enabling liquid coolant to flow from input 155 to output 156. An electronic component 159 mounted on substrate 158 is shown thermally coupled to cold plate 151 using a thermal interface material (TIM) 157. Electronic component 159 may be a high-powered chip, such as a B200 chip manufactured by NVIDIA CORPORATION, dissipating heat at a rate of 1200 watts for example, made possible by the cooling provided by cold plate 231. Multiple chips or other heat-producing electronic components 159 may be thermally coupled to one or both sides of cold plate 231.

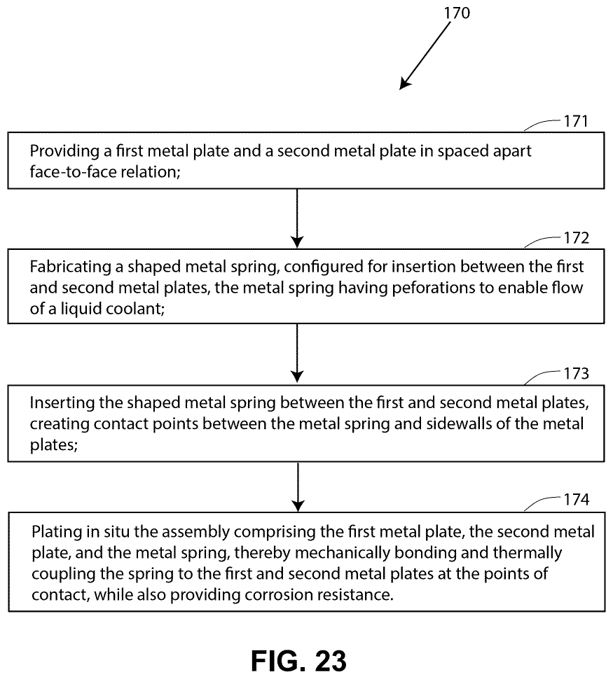

FIG. 23 shows a method 170 for manufacturing a convective cooling channel configured for flow of a liquid coolant, in accordance with an embodiment of the present disclosure. The reference numerals used to refer to components used in this method are exemplary and can be chosen from any of the embodiments of the convective cooling channels or the cold plate, respectively, 10, 40, 70, 90, 133, or 151, described above. The method 170 begins at step 171, providing a first metal plate and a second metal plate, for example, the metal plates 41a, 41b, in spaced apart face-to-face relation. The method 170 continues at step 172, fabricating a shaped metal spring, for example, the shaped metal spring 42, configured for insertion between the first and second metal plates 41a, 41b, the shaped metal spring 42 having perforations, for example, perforations 61, 62 to enable flow of a liquid coolant. Alternatively, step 172 is the fabricating of a piece of porous metallic material 183 configured for insertion between the first and second metal plates 41a, 41b, the piece of porous metallic material having a thickness that spans the space between the first and second metal plates 41a, 41b.

The method 170 continues at step 173, inserting the shaped metal spring 42 between the first and second metal plates 41a, 41b, creating contact points between the shaped metal spring 42 and sidewalls of the metal plates 41a, 41b. Alternatively, step 173 is inserting the piece of porous metallic material 183 between the first and second metal plates 41a, 41b, creating contact between the piece of porous metallic material 183 and sidewalls of the metal plates 41a, 41b. The method 170 continues at step 174, plating in situ the assembly comprising the first metal plate 41a, the second metal plate 41b, and the shaped metal spring 42, thereby mechanically bonding and thermally coupling the shaped metal spring 42 to the first and second metal plates 41a, 41b at the points of contact, while also providing corrosion resistance. Alternatively, step 174 is plating in situ the assembly comprising the first metal plate 41a, the second metal plate 41b, and the piece of porous metallic material 183, thereby mechanically bonding and thermally coupling the piece of porous metallic material 183 to the first and second metal plates 41a, 41b, while also providing corrosion resistance.

As will be understood by those familiar with the art, the invention may be embodied in other specific forms without departing from the spirit or essential characteristics thereof. Likewise, the particular naming and division of the members, features, attributes, and other aspects are not mandatory or significant, and the mechanisms that implement the invention or its features may have different structural construct, names, and divisions. Accordingly, the disclosure of the invention is intended to be illustrative, but not limiting, of the scope of the invention.

While the invention has been described in terms of several embodiments, those of ordinary skill in the art will recognize that the invention is not limited to the embodiments described but can be practiced with modification and alteration within the spirit and scope of the appended claims. For example, another embodiment may comprise a convective cooling apparatus having cylindrical or spherical metal plates, adapted to encircle or enclose a small modular reactor (SMR). In cryogenic cooling environments, liquid nitrogen or liquid helium or liquid hydrogen may be used as the coolant. Other embodiments may have different overall sizes and form factors for the convective cooling channel. The description is thus to be regarded as illustrative instead of limiting. There are numerous other variations to different aspects of the invention described above, which in the interest of conciseness have not been provided in detail. Accordingly, other embodiments are within the scope of the claims.

The invention has been described in relation to particular examples, which are intended in all respects to be illustrative rather than restrictive. Those skilled in the art will appreciate that many different combinations will be suitable for practicing the present invention. For example, the teachings may be applied to other fluid-cooled electronic systems, especially those with space limitations or aggressive cooling requirements. Other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

It should be understood that the drawings and detailed description herein are to be regarded in an illustrative rather than a restrictive manner, and are not intended to be limiting to the particular forms and examples disclosed. On the contrary, included are any further modifications, changes, rearrangements, substitutions, alternatives, design choices, and embodiments apparent to those of ordinary skill in the art, without departing from the spirit and scope hereof.

1. A convective cooling apparatus, comprising:
a first metal plate and a second metal plate defining a primary passage therebetween; and
a shaped metallic insert disposed within said primary passage, the metallic insert comprising a metal sheet formed into a non-planar geometry having a plurality of faces, wherein said faces include perforations configured to permit liquid coolant to flow therethrough and to induce mixing of said coolant.

2. The convective cooling apparatus of claim 1, wherein the first metal plate and the second metal plate comprise external fins of a heat sink or thermal sheath.

3. The convective cooling apparatus of claim 1 wherein the first metal plate and the second metal plate comprise opposing plates of a cold plate.

4. The convective cooling apparatus of claim 1 wherein the shaped metallic insert comprises a metal foil.

5. The convective cooling apparatus of claim 1 wherein the shaped metallic insert comprises a woven metallic fabric, a spring-like material, or a combination thereof.

6. The convective cooling apparatus of claim 1, the metallic insert comprising a piece of porous metallic material having a thickness, the thickness substantially spanning the primary passage, the piece of porous metallic material being composed of a structured metal defining a network of interconnected micropores, wherein the interconnected micropores are configured to permit the liquid coolant to flow through the piece of porous metallic material from the inlet to the outlet of the primary passage.

7. A convective cooling channel comprising:
a first metal plate and a second metal plate positioned in a spaced apart, face-to-face relationship, thereby defining a primary passage therebetween; and
a sheet of porous metallic material occupying said primary passage by spanning the space between the corresponding two metal plates,
wherein a liquid coolant is configured to flow through said porous metallic material in said primary passage.

8. The convective cooling channel of claim 7, wherein the first metal plate and the second metal plate constitute external fins of a heat sink or a thermal sheath.

9. The convective cooling channel of claim 7 wherein the first metal plate and the second metal plate constitute opposing plates of a cold plate.

10. The convective cooling channel of claim 7 wherein the sheet of porous metallic material comprises an open cell metal foam.

11. The convective cooling channel of claim 7 wherein the sheet of porous metallic material comprises a woven metallic fabric.

12. The convective cooling channel of claim 7, further comprising the liquid coolant, wherein the liquid coolant is selected from the group consisting of treated water, a dielectric fluid, a refrigerant, glycol, or any combination thereof.

13. The convective cooling channel of claim 7, wherein the sheet of porous metallic material and internal sidewalls of the first metal plate and the second metal plate that define the primary passage are coated with a corrosion-resistant material.

14. The convective cooling channel of claim 13 wherein the corrosion resistant material comprises nickel.

15. The convective cooling channel of claim 7, wherein the sheet of porous metallic material is affixed to internal sidewalls of the first metal plate and the second metal plate that define the primary passage by a method selected from the group consisting of soldering, welding, brazing, sintering, and applying a build-up layer of plated material.

16. A thermal sheath for a circuit board assembly, comprising:
a body constructed of a thermally conductive material, the body defining an internal pocket configured to receive the circuit board assembly; and
a piece of porous metallic material affixed to each of at least two opposing external sidewalls of the body, wherein the piece of porous metallic material is configured to permit a liquid coolant to flow through the porous metallic material to enhance heat transfer between the body and the liquid coolant.

17. The thermal sheath of claim 16, wherein the body has a substantially rectangular prism shape.

18. The thermal sheath of claim 16 wherein said porous metallic material is selected from the group consisting of an open-cell copper foam and a woven metallic fabric.

19. A computer module, comprising:
a circuit board assembly having electronic components mounted thereon; and
a thermal sheath housing said circuit board assembly, said thermal sheath comprising:
a body formed of a thermally conductive material and defining an internal pocket, said internal pocket being shaped to receive said circuit board assembly and having an access opening;
a sealing assembly coupled to said body at said access opening, said sealing assembly comprising a gasket and a gasket backing plate, wherein said sealing assembly is configured to create a liquid-tight seal at said access opening to protect said circuit board assembly from an external liquid coolant, said thermal sheath further comprising at least one sheet of porous metallic material affixed to at least two opposing external sidewalls of said body.

20. A computer server, comprising:
a tank configured to contain a flowing liquid coolant; and
a plurality of computer modules juxtaposed within said tank and partially immersed in said flowing liquid coolant, each of said computer modules comprising:
a circuit board assembly including a plurality of electronic components mounted on a substrate; and
a thermal sheath substantially enclosing said circuit board assembly, said thermal sheath comprising:
a body constructed of a thermally conductive material, said body having a substantially rectangular prism shape and defining an internal pocket dimensioned to receive and support said circuit board assembly, said body further having an opening providing access to said internal pocket;
at least one sheet of porous metallic material affixed to at least two opposing external sidewalls of said body;
a gasket positioned at said opening; and
a gasket backing plate operatively associated with said gasket and said body to compress said gasket against a sealing surface, thereby forming a seal to prevent intrusion of said flowing liquid coolant from said tank into said internal pocket, wherein said thermally conductive material of said body and said sheet of porous metallic material are configured to transfer heat from said circuit board assembly to said flowing liquid coolant.

21. The computer server of claim 20, wherein the porous metallic material is selected from the group consisting of an open-cell copper foam and a woven metallic fabric.

22. The computer server of claim 20, wherein each of said computer modules further comprises:
an extended portion of said substrate, said extended portion being substantially free of said plurality of electronic components and including a plurality of conductive traces thereon; and
one or more electrical connectors operatively coupled to said conductive traces on said extended portion of said substrate, said one or more electrical connectors having socket terminals;
and wherein the computer server further comprises a motherboard having motherboard terminals configured to connect to said socket terminals of the one or more electrical connectors of each of said computer modules, thereby facilitating electrical communication between said circuit board assembly within said thermal sheath and said motherboard located external to said thermal sheath.
